(19) United States
(12) Patent Application Publication
(10) Pub. No.: US 2025/0113710 A1
(43) Pub. Date: Apr. 3, 2025

(54) DISPLAY PANEL AND DISPLAY APPARATUS

(71) Applicants: Hefei Visionox Technology Co., Ltd., Hefei (CN); KunShan Go-Visionox Opto Electronics Co., Ltd, Kunshan (CN)

(72) Inventors: Wenyu ZENG, Hefei (CN); Ying SHEN, Hefei (CN); Zhihui XIAO, Hefei (CN)

(73) Assignees: Hefei Visionox Technology Co., Ltd., Hefei (CN); KunShan Go-Visionox Opto Electronics Co., Ltd, Kunshan (CN)

(21) Appl. No.: 18/650,275

(22) Filed: Apr. 30, 2024

(30) Foreign Application Priority Data
Sep. 28, 2023 (CN) 202311279242.4

(51) Int. Cl. H10K 59/126; H10K 59/122; H10K 59/131; H10K 59/40

(52) U.S. Cl. CPC H10K 59/126; H10K 59/122; H10K 59/131; H10K 59/40

(57) ABSTRACT

A display panel and a display apparatus. The display panel includes a substrate, an isolation structure and a touch layer. The isolation structure is arranged on the substrate and encloses a plurality of isolation openings. The isolation structure is provided with a light-transmitting opening. The substrate includes a signal transmission layer and a signal shielding layer, the signal shielding layer is located on a side of the signal transmission layer away from the substrate, and the signal shielding layer includes a first signal line and a light-transmitting shielding portion. The orthographic projection of the light-transmitting opening on the substrate at least partially overlaps with an orthographic projection of the light-transmitting shielding portion on the substrate.

### CROSS REFERENCE TO RELATED APPLICATION

The present application claims priority to Chinese Patent Application No. 202311279242.4 filed on Sep. 28, 2023, which is incorporated herein by reference in its entirety.

### TECHNICAL FIELD

This application relates to the field of display, and particularly to a display panel and a display apparatus.

### BACKGROUND

An organic light-emitting diodes (OLED) and a flat display apparatus based on a technology such as light-emitting diode (LED) are widely used in various consumer electronic products such as mobile phones, televisions, notebook computers, desktop computers due to their advantages of high picture quality, power saving, a thin body and a wide range of applications, and become the mainstream of display devices.

However, the usage performance of the current OLED product needs to be improved.

### SUMMARY

Embodiments of the present application provide a display panel and a display apparatus.

Embodiments in a first aspect of the present application provide a display panel, including: a substrate including a signal transmission layer and signal shielding layer, the signal shielding layer located on a side of the signal transmission layer away from the substrate, and the signal shielding layer having at least one first signal line and a light-transmitting shielding portion; a light-emitting unit disposed on the substrate; an isolation structure located on a side of the substrate and defined with an isolation opening for receiving the light-emitting unit and a light-transmitting opening, and an orthographic projection of the light-transmitting opening on the substrate at least partially overlaps with an orthographic projection of the light-transmitting shielding portion on the substrate; and a touch layer located on a side of the signal shielding layer away from the signal transmission layer.

Embodiments in a second aspect of the present application provide a display apparatus including the display panel as described in any of the above implementations.

### BRIEF DESCRIPTION OF THE DRAWINGS

Other features, objects and advantages of the present application will become more apparent upon reading the following detailed description of non-limiting embodiments with reference to the accompanying drawings, wherein the same or similar reference signs indicate the same or similar features and the accompanying drawings are not drawn to actual scale.

FIG. 1 is a schematic cross-sectional diagram of a display panel provided according to an embodiment of the present application.

FIG. 2 is a schematic top-view diagram of a display panel provided according to an embodiment of the present application.

FIG. 3 is a partial cross-sectional diagram of a display panel in another embodiment of the present application.

FIG. 4 is a partial top-view diagram of a display panel in another embodiment of the present application.

FIG. 5 is a partial top-view diagram of a display panel in yet another embodiment of the present application.

FIG. 6 is a partial top-view diagram of a display panel in still another embodiment of the present application.

FIG. 7 is a partial cross-sectional diagram of a display panel in yet another embodiment of the present application.

FIG. 8 is a partial cross-sectional diagram of a display panel in still another embodiment of the present application.

FIG. 9 is a partial top-view diagram of a display panel in yet still another embodiment of the present application.

FIG. 10 is a partial cross-sectional diagram of a display panel in yet still another embodiment of the present application.

FIG. 11 is a partial cross-sectional diagram of a display panel in yet still another embodiment of the present application.

FIG. 12 is schematic flowchart of a method for manufacturing a display panel provided according to an embodiment of the present application.

### DESCRIPTION OF REFERENCE SIGNS

10: display panel;
100: substrate; 110: signal transmission layer; 120: signal shielding layer; 121: first signal line; 122: light-transmitting shielding portion; 123: gap; 124: first opening; 125: second signal line;
200: isolation structure; 210: first conductive layer; 220: second layer; 230: third layer; 240: isolation opening; 250: light-transmitting opening.
300: touch layer;
400: light-emitting layer; 410: light-emitting unit;
500: first electrode layer; 510: first electrode;
600: pixel definition layer; 610: pixel limiting portion; 620: pixel opening; 630: second opening; 640: pixel electrode;
700: encapsulation layer; 710: first sub-layer; 711: first sub-portion; 720: second sub-layer; 721: second sub-portion; 730: third sub-layer.

### DETAILED DESCRIPTION

Features and exemplary embodiments of various aspects of the present application will be described in detailed below. In order to make the objects, technical solutions and advantages of the present application clearer, the present application is further described in details below with reference to the accompany drawings and specific embodiments. It should be understood that the specific embodiments described herein are only for illustration of the present application, and are not for limiting the present application. For those skilled in the art, the present application can be implemented without some of those specific details. The below description of embodiments is only for providing better understanding of the present application by showing examples of the present application.

It should be noted that, in the present application, relational terms such as first and second are used only to distinguish one entity or operation from another entity or operation, and do not necessarily require or imply any such actual relationship or sequence exists between these entities or operations. Moreover, the terms “include,” “comprise,” or any variants thereof are intended to cover a non-exclusive inclusion, such that processes, methods, articles, or devices, including a series of elements, include not only those elements that have been listed, but also other elements that have not specifically been listed or the elements intrinsic to these processes, methods, articles, or devices. Without further limitations, elements limited by the wording “comprise(s)/include(s) a/an . . . ” do not exclude additional identical elements in the processes, methods, articles, or devices including the listed elements.

It should be understood that when a structure of a component is described, a layer or region being arranged “above” or “on” another layer or region, means that the layer or region is directly on the another layer or region, or that there is another layer or region between the layer or region and the another layer or region. Moreover, if the component is reversed, the layer or region will be located “below” or “under” the another layer or region.

Embodiments of the present application provide a display panel, a display apparatus, and a method for manufacturing a display panel. Various embodiments of the display panel, the display apparatus, and the method for manufacturing a display panel will be described below with reference to the accompanying drawings.

An embodiment of the present application provides a display panel. The display panel is an OLED display panel.

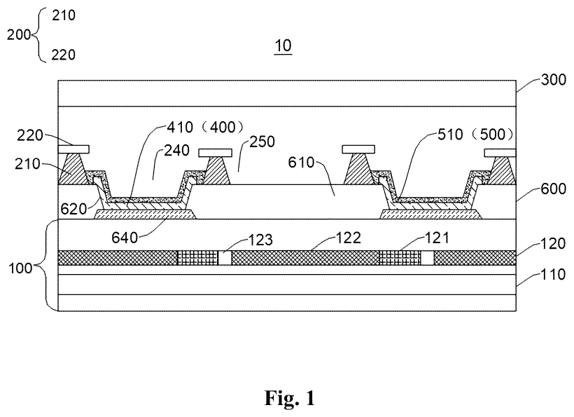

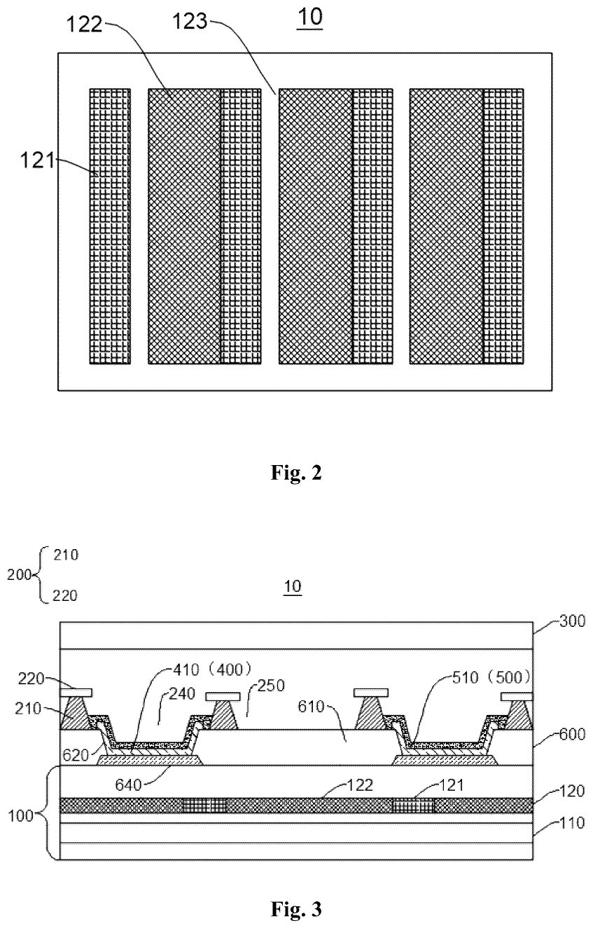

Referring to FIG. 1 and FIG. 2 together, FIG. 1 is a schematic cross-sectional diagram of a display panel provided according to an embodiment of the present application, and FIG. 2 is a schematic top-view diagram of a display panel provided according to an embodiment of the present application.

As shown in FIGS. 1 and 2, an embodiment in a first aspect of the present application provide a display panel 10, which includes a substrate 100, an isolation structure 200 and a touch layer 300. The substrate 100 includes a signal transmission layer 110 and a signal shielding layer 120, the signal shielding layer 120 is located on a side of the signal transmission layer 110 away from the substrate 100, and the signal shielding layer 120 includes a first signal line 121 and a light-transmitting shielding portion 122. The isolation structure 200 is located on a side of the substrate 100, and the isolation structure 200 encloses an isolation opening 240 and a light-transmitting opening 250, the isolation opening 240 is used for setting up a light-emitting unit 410. An orthographic projection of the light-transmitting opening 250 on the substrate 100 at least partially overlaps with an orthographic projection of the light-transmitting shielding portion 122 on the substrate 100. The touch layer 300 is located on a side of the signal shielding layer 120 away from the signal transmission layer 110.

According to the embodiment of the present application, the display panel 10 includes a substrate 100, an isolation structure 200 and a touch layer 300. The isolation structure 200 is arranged on the substrate 100 and encloses a plurality of isolation openings 240 for isolating the light-emitting layer 400 to form light-emitting units 410 separated from each other, thereby reducing the crosstalk of carriers in the light-emitting layer 400 and improving the display effect of the display panel 10. In addition, the manufacturing of the light-emitting units 410 does not need to use a fine metal mask, which can reduce the development and use of the fine metal mask and reduce the manufacturing cost. The isolation structure 200 is provided with a light-transmitting opening 250, which can improve the transmittance of the display panel 10. The substrate 100 includes a signal transmission layer 110 and a signal shielding layer 120, the signal shielding layer 120 includes a first signal line 121 and a light-transmitting shielding portion 122, and the signal shielding layer 120 is located on a side of the signal transmission layer 110 away from the substrate 100. The orthographic projection of the light-transmitting opening 250 on the substrate 100 at least partially overlaps with an orthographic projection of the light-transmitting shielding portion 122 on the substrate 100, that is, the light-transmitting shielding portion 122 covers at least part of the light-transmitting opening 250, so that touch signals of the touch layer 130 are at least partially shielded by the light-transmitting shielding portion 122 after passing through the light-transmitting opening, which makes improvements on the problem that the touch signal of the touch layer 300 and the array signal of the substrate 100 influence each other through the light-transmitting opening 250, thereby improving the usage performance of the OLED display panel.

When the first signal line 121 and the light-transmitting shielding portion 122 are arranged on the same layer, it is convenient for the lapping of the first signal line 121 and the light-transmitting shielding portion 122, so that the first signal line 121 and the light-transmitting shielding portion 122 share a common potential, and the light-transmitting shielding portion 122 does not need to use any other means for potential connection. In addition, the first signal line 121 and the light-transmitting shielding portion 122 share a flat layer, which can make improvements on the problem that an additional flat layer needs to be arranged between the first signal line 121 and the light-transmitting shielding portion 122 when they are arranged in different layers, and the manufacturing process of the display panel 10 can be simplified.

Optionally, the touch layer 300 includes a touch electrode, and an orthographic projection of the touch electrode on the substrate 100 does not overlap with the orthographic projection of the light-transmitting opening 250 on the substrate 100, so as to prevent the touch electrode from blocking the light-transmitting opening 250 and affecting the light-transmitting performance.

Optionally, the light-transmitting shielding portion 122 is connected with the first signal line 121. The light-transmitting shielding portion 122 is lapped to the first signal line 121, so that the light-transmitting shielding portion 122 has the same potential as the first signal line 121, and the shielding function of the light-transmitting shielding portion 122 can be realized.

In some optional embodiments, there are a plurality of first signal lines 121 arranged side by side, adjacent first signal lines 121 of the plurality of first signal lines 121 are arranged at an interval and a gap 123 is formed between the adjacent first signal lines 121, and the light-transmitting shielding portion 122 is located in the gap 123.

In these optional embodiments, the adjacent first signal lines 121 are arranged at an interval to form a gap 123, and the light-transmitting shielding portion 122 is arranged in the gap 123, and both sides of the light-transmitting shielding portion 122 is provided with a first signal line 121, it is convenient for the light-transmitting shielding portion 122 to be lapped to the first signal line 121, so that the light-transmitting shielding portion 122 can be electrically connected with the first signal line 121 and the light-transmitting shielding portion 122 can have the same potential with the first signal line 121.

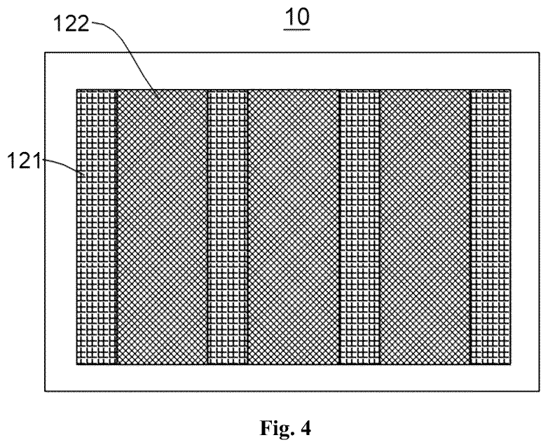

Referring to FIGS. 1 to 4 together, FIG. 3 is a partial cross-sectional diagram of a display panel in another embodiment of the present application, and FIG. 4 is a partial top-view diagram of a display panel in another embodiment of the present application.

As shown in FIGS. 1 to 4, optionally, the light-transmitting shielding portion 122 is electrically connected with one or more first signal lines 121 adjacent to the light-transmitting shielding portion 122. The light-transmitting shielding portion 122 is lapped to its two adjacent first signal lines 121, so that the first signal lines 121 on both sides of the light-transmitting shielding portion 122 are electrically connected with the light-transmitting shielding portion 122, so as to make improvements on the problems that the voltage drop of the light-transmitting shielding portion 122 due to the one-side electrical connection with the first signal line 121 causes poor potential uniformity of the light-transmitting shielding portion 122, and improve the potential uniformity of the light-transmitting shielding portion 122, thereby improving the shielding effect of the light-transmitting shielding portion 122.

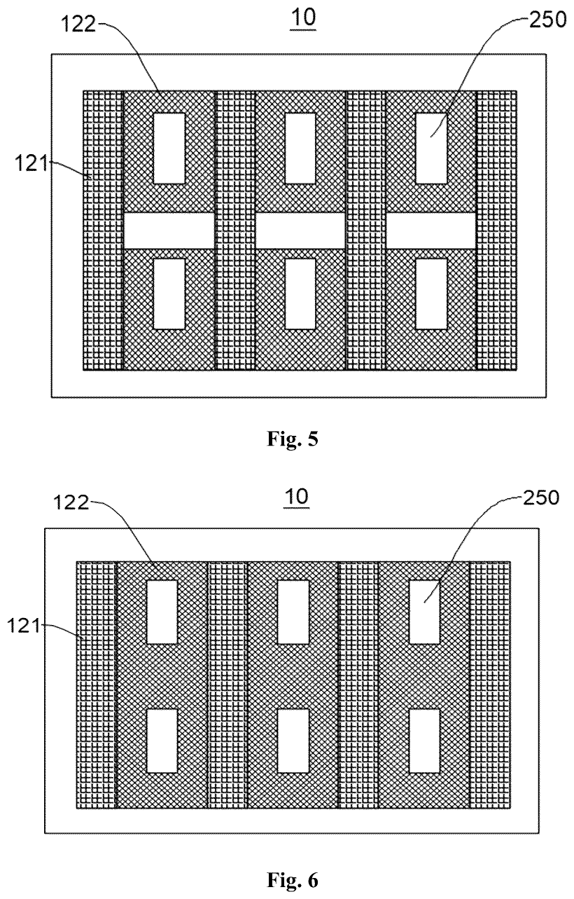

Referring to FIGS. 5 and 6 together, FIG. 5 is a partial top-view diagram of a display panel in yet another embodiment of the present application, FIG. 6 is a partial top-view diagram of a display panel in still another embodiment of the present application.

In some optional embodiments, as shown in FIG. 5, one light-transmitting shielding portion 122 is arranged corresponding to one light-transmitting opening 250, and/or as shown in FIG. 6, one light-transmitting shield portion 122 is arranged corresponding to a plurality of light-transmitting openings 250.

One light-transmitting shielding portion 122 is arranged corresponding to one light-transmitting opening 250, that is, an orthographic projection of one light-transmitting opening 250 on the substrate 100 is within the orthographic projection of the light-transmitting shielding portion 122 on the substrate 100. One light-transmitting shield portion 122 is arranged corresponding to a plurality of light-transmitting openings 250, that is, orthographic projections of the plurality of light-transmitting openings 250 on the substrate 100 are within the orthographic projection of the same light-transmitting shielding portion 122 on the substrate 100.

In these optional embodiments, one light-transmitting shielding portion 122 arranged corresponding to one light-transmitting opening 250 can reduce the overall area of the light-transmitting shielding portion 122 and reduce the material cost. One light-transmitting shield portion 122 arranged corresponding to a plurality of light-transmitting openings 250 can increase the lap area between the light-transmitting shielding portion 122 and the first signal line 121, reduce the lap impedance, and improve the shielding effect of the light-transmitting shielding portion 122.

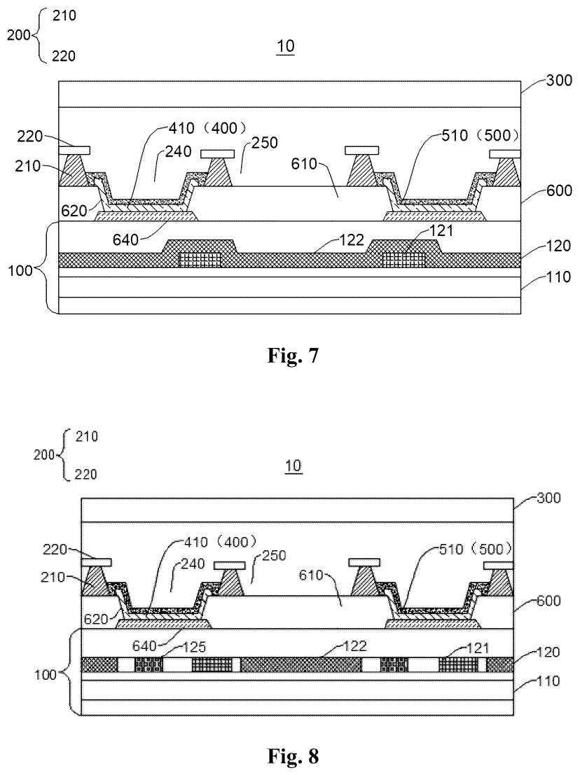

Please refer to FIG. 7, which is a partial cross-sectional diagram of a display panel in yet another embodiment of the present application.

As shown in FIG. 7, optionally, the orthographic projection of the light-transmitting shielding portion 122 on the substrate 100 at least partially overlaps with the orthographic projection of the first signal line 121 on the substrate 100, that is, the light-transmitting shielding portion 122 is arranged to cover at least part of the first signal line 121, so as to increase the lap area between the light-transmitting shielding portion 122 and the first signal line 121, thereby reducing the contact resistance between the light-transmitting shielding portion 122 and the first signal line 121 to improve the shielding effect of the light-transmitting shielding portion 122.

Optionally, the orthographic projection of the first signal line 121 on the substrate 100 is within the orthographic projection of the light-transmitting shielding portion 122 on the substrate 100, that is, the first signal line 121 is completely covered by the light-transmitting shielding portion 122. The part of the light-transmitting shielding portion 122 located on the first signal line 121 does not need to be etched, the manufacturing process can be simplified, the contact area of the light-transmitting shielding portion 122 and the first signal line 121 can be further increased, the contact resistance between the light-transmitting shielding portion 122 and the first signal line 121 can be reduced, and the shielding effect of light-transmitting shielding portion 122 can be improved.

Please refer to FIGS. 8 and 9, FIG. 8 is a partial cross-sectional diagram of a display panel in still another embodiment of the present application, and FIG. 9 is a partial top-view diagram of a display panel in yet still another embodiment of the present application.

As shown in FIGS. 8 and 9, in some optional embodiments, the light-transmitting shielding portion 122 encloses a first opening 124, the signal shielding layer 120 further includes a second signal line 125, the first signal line 121 and the second signal line 125 are located in the first opening 124, and the second signal line 125 is spaced and insulated from the light-transmitting shielding portion 122.

In these optional embodiments, the light-transmitting shielding portion 122 encloses the first opening 124 to provide a certain space for setting up the first signal line 121 and the second signal line 125, the first signal line 121 is located in the first opening 124, the first signal line 121 is surrounded by the light-transmitting shielding portion 122, which facilitates the lap of the first signal line 121 and the light-transmitting shielding portion 122. The second signal line 125 is arranged in the first opening 124 to realize the signal transmission function. The second signal line 125 is spaced and insulated from the light-transmitting shielding portion 122, which makes it difficult to electrically connect the second signal line 125 with the first signal line 121 to produce a short circuit, thus improving the reliability of the first signal line 121 and the second signal line 125.

The second signal line 125 is optional, and both ends of the first signal line 121 are lapped to the light-transmitting shielding portion 122, so as to make improvements on the problems that the voltage drop of the light-transmitting shielding portion 122 due to the one-side electrical connection with the first signal line 121 causes poor potential uniformity of the light-transmitting shielding portion 122, and improve the potential uniformity of the light-transmitting shielding portion 122, thereby improving the shielding effect of the light-transmitting shielding portion 122.

Optionally, the orthographic projection of the light-transmitting opening 250 on the substrate 100 is within the orthographic projection of the light-transmitting shielding portion 122 on the substrate 100, so that the light-transmitting opening 250 can be completely covered by the light-transmitting shielding portion 122, which enables the touch signal of the touch layer 300 to be shielded by the light-transmitting shielding portion 122 after the signal passing through the light-transmitting opening 250.

Optionally, a material of the light-transmitting shielding portion 122 is different from that of the first signal line 121, and the first signal line 121 is a non-light-transmission conductive material. For example, the first signal line 121 is a metal conductive material with low resistance, which can reduce the power consumption of the display panel.

Optionally, the light-transmitting shielding portion 122 includes indium tin oxide (ITO) or indium zinc oxide (IZO). When the light-transmitting shielding portion 122 is ITO or IZO, it has a good transmittance and can be electrically communicated with the first signal line 121.

Optionally, the first signal line 121 includes a power signal line and/or a reference signal line, the second signal line 125 includes a data signal line.

In some optional embodiments, the display panel 10 also includes a light-emitting layer 400 and a first electrode layer 500. The light-emitting layer 400 is located on a side of the substrate 100, the light-emitting layer 400 includes the light-emitting unit 410 located in the isolation opening 240. The first electrode layer 500 is located on a side of the light-emitting layer 400 away from the substrate 100, the first electrode layer 500 includes a first electrode 510 located in the isolation opening 240, and the first electrode 510 is electrically connected with the isolation structure 200.

In these optional embodiments, the isolation structure 200 separates the first electrode layer 500 to form first electrodes 510 separated with each other, and the separated first electrodes 510 are electrically connected by the isolation structure 200 to form a whole-plane electrode to ensure the normal light-emitting of the light-emitting unit 410.

In some optional embodiments, an orthographic projection of each light-emitting unit 410 on the substrate 100 is within an orthographic projection of a corresponding first electrode 510 on the substrate 100.

In these optional embodiments, the orthographic projection of the light-emitting unit 410 on the substrate 100 is within the orthographic projection of the first electrode 510 on the substrate 100, that is, the first electrode 510 is arranged to cover the light-emitting unit 410 and is arranged as the electrode of the light-emitting unit 410 to ensure the normal light-emitting of the light-emitting unit 410 and improve the display effect of the display panel 10.

Optionally, the light-emitting unit 410 is spaced from the isolation structure 200. that is, the light-emitting units 410 are separated from each other to reduce the crosstalk of carriers between light-emitting units 410 and improve the cross-color problem of the light-emitting units 410.

In some optional embodiments, the isolation structure 200 includes a first conductive layer 210 and a second layer 220 located on a side of the first conductive layer 210 away from the substrate 100, and an orthographic projection of the first conductive layer 210 on the substrate 100 is within an orthographic projection of the second layer 220 on the substrate 100.

In these optional embodiments, the first conductive layer 210 and the second layer 220 are arranged to form an isolation structure 200, the first conductive layer 210 is arranged near the substrate 100, an orthographic projection of the first conductive layer 210 on the substrate 100 is within an orthographic projection of the second layer 220 on the substrate 100, the area of the second layer 220 is larger than that of the first conductive layer 210, and the second layer 220 covers the surface of the first conductive layer 210 near the second layer 220, at this time, the first conductive layer 210 is concave relative to the second layer 220 in a direction away from the isolation opening 240. When manufacturing the light-emitting layer 400, the light-emitting layer 400 produces a large drop at the edge of the isolation structures 200, since the first conductive layer 210 is concave relative to the second layer 220, the light-emitting layer 400 is difficult to keep connected at the edges of the isolation structures 200 and is broken at the edges of the isolation structures 200, the light-emitting layer 400 is broken into light-emitting units 410 disconnected with each other.

In some optional embodiments, the second layer 220 includes a conductive material or an insulating material.

In these optional embodiments, the second layer 220 includes a conductive material, such as a non-metal conductive material or a metal conductive material. When the second layer 220 is a non-metal conductive material or an insulating material, the second layer 220 is difficult to be etched in the process of wet etching the first conductive layer 210 with an etching solution, thus making it easier to realize the concave setting of the first conductive layer 210 relative to the second layer 220.

In some optional embodiments, the second layer 220 includes a metal material, and a material of the first conductive layer 210 is different from that of the second layer 220.

In these optional embodiments, when both of the first conductive layer 210 and the second layer 220 are metal materials, the first conductive layer 210 may be wet etched with an etching solution, and by setting the etching solution, the etching rate of the second layer 220 can be set to be less than that of the first conductive layer 210. When the first conductive layer 210 is wet etched with the etching solution, even the second layer 220 will also be etched to a certain extent, since the etching rate of the first conductive layer 210 is lager, the first conductive layer 210 will be etched faster, so that the first conductive layer 210 can be arranged to be concave relative to the second layer 220.

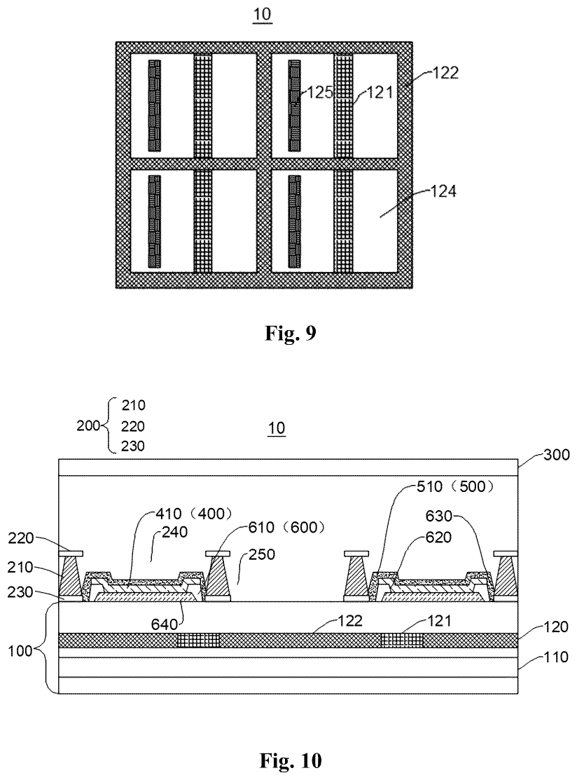

Please refer to FIG. 10, which is a partial cross-sectional diagram of a display panel in yet still another embodiment of the present application.

As shown in FIG. 10, in some optional embodiments, the isolation structure 200 further includes a third layer 230 located on a side of the first conductive layer 210 facing the substrate 100, and the orthographic projection of the first conductive layer 210 on the substrate 100 is within an orthographic projection of the third layer 230 on the substrate 100.

In these optional embodiments, in order to obtain the first conductive layer 210 with a concave setting, the first conductive layer 210 has a faster etching rate than the second layer 220 and the third layer 230 in the etching process, thereby forming the concave first conductive layer 210. Due to the fast etching rate of the first conductive layer 210, the waste generated by the etching is easy to enter into other positions of the display panel 10, thus causing adverse effects. After setting the third layer 230, the first conductive layer 210 can be better attached to the third layer 230, and the resulting etching waste will fall on the third layer 230, which is easy to clean.

In some optional embodiments, the display panel 10 further includes a pixel definition layer 600 located on a side of the substrate 100, the pixel definition layer 600 includes a pixel limiting portion 610 and a pixel opening 620 enclosed by the pixel limiting portion 610, the pixel opening 620 is communicated with the isolation opening 240, and the light-emitting unit 410 is located in the pixel opening 620.

In these optional embodiments, the pixel opening 620 enclosed by the pixel limiting section 610 is used for setting up the light-emitting unit 410 to realize the luminous display of the display panel 10. The pixel opening 620 is arranged in communication with the isolation opening 240, which reduces the block of the isolation structure 200 to the pixel opening 620 and ensures the light-emitting effect of the light-emitting unit 410.

In some optional embodiments, the isolation structure 200 is located on a side of the pixel limiting portion 610 away from the substrate 100.

In these optional embodiments, the isolation structure 200 is arranged on the pixel limiting portion 610 and the isolation structure 200 has a large height drop relative to the pixel opening 620. When manufacturing the light-emitting layer 400, due to the large drop, the light-emitting layer 400 is easier to be broken at the position of the isolation structure 200, thus reducing the manufacturing difficulty of the light-emitting layer 400.

As shown in FIG. 10, in some optional embodiments, the pixel limiting portion 610 is provided with a second opening 630, and the isolation structure 200 is located in the second opening 630.

In these optional embodiments, the isolation structure 200 is arranged in the second opening 630 on the pixel limiting portion 610. During the manufacturing process, the isolation structure 200 is manufactured before the manufacturing of the pixel electrode 640, that is, after the isolation structure 200 is manufactured on the substrate 100, the pixel electrode 640 is then manufactured on the substrate 100 to reduce the effect of the manufacturing of the isolation structure 200 on the pixel electrode 640 and ensure that the pixel electrode 640 is not damaged.

Optionally, the display panel 10 further includes a pixel electrode 640 exposed by the pixel opening 620, one of the pixel electrode 640 and the first electrode 510 serves as the anode of the light-emitting unit 410 and the other serves as the cathode of the light-emitting unit 410. The embodiment of the present application is illustrated by taking the pixel electrode 640 as the anode of the light-emitting unit 410 and the first electrode 510 as the cathode of the light-emitting unit 410.

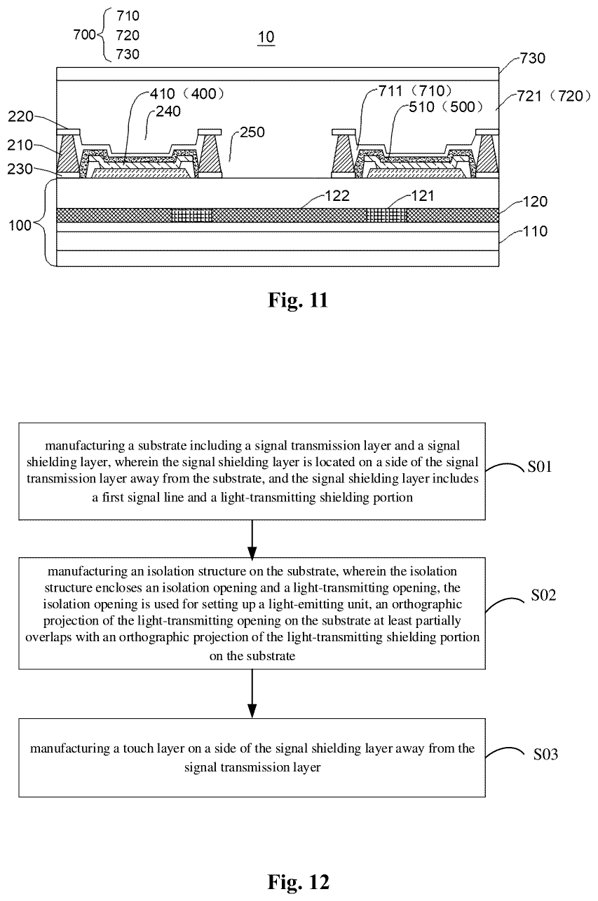

Please refer to FIG. 11, which is a partial cross-sectional diagram of a display panel in yet still another embodiment of the present application.

As shown in FIG. 11, in some optional embodiments, the display panel 10 further includes an encapsulation layer 700 located on a side of the first electrode 510 away from the substrate 100.

In these optional embodiments, the encapsulation layer 700 is arranged on a side of the first electrode 510 away from the substrate 100 to encapsulate the first electrode 510 and the light-emitting layer 400, so as to reduce the possibility of water and oxygen intrusion and improve the service life of the display panel 10.

In some optional embodiments, the encapsulation layer 700 includes a first sub-layer 710, which is located on a side of the light-emitting layer 400 away from the substrate 100.

In these optional embodiments, the first sub-layer 710 is arranged on the side of the first electrode 510 away from the substrate 100 to encapsulate the first electrode 510 and the light-emitting layer 400, so as to reduce the possibility of water and oxygen intrusion and improve the service life of the display panel 10.

Optionally, the first sub-layer 710 includes a first sub-portion 711, which is located in the isolation opening 240, and a projection of the first sub-portion 711 on the substrate 100 covers the light-emitting unit 410, so as to achieve a first encapsulation of the light-emitting unit 410 and the first electrode 510.

Optionally, the first sub-layer 710 includes an inorganic material, which have good compactness and good barrier to water vapor and oxygen.

In some optional embodiments, the encapsulation layer 700 further includes a second sub-layer 720, which is located on a side of the first sub-layer 710 away from the substrate 100.

In these optional embodiments, the encapsulation layer 700 includes a first sub-layer 710 and a second sub-layer 720, and the first sub-layer 710 and the second sub-layer 720 are used for multi-layer encapsulation, so as to further improve the encapsulation performance of the encapsulation layer 700.

Optionally, the second sub-layer 720 includes a second sub-portion 721, and a part of the second sub-layer 721 is filled in the light-transmitting opening 250 to realize the planarization of the first opening.

Optionally, the second sub-layer 720 includes an organic material, and the second sub-layer 720 is encapsulated with an organic material to further improve the encapsulation performance of the encapsulation layer 700.

Optionally, the encapsulation layer 700 further includes a third sub-layer 730, the third sub-layer 730 is located on a side of the second sub-layer 720 away from the substrate 100. The encapsulation layer 700 adopts three-layer encapsulation, which has better encapsulation performance and reduces the possibility of water and oxygen intrusion.

Optionally, the third sub-layer 730 includes an inorganic material, and the first sub-layer 710, the second sub-layer 720 and the third sub-layer 730 are encapsulated with an inorganic material, an organic material and an inorganic material, respectively, to form a thin film encapsulation (TFE) structure to further improve the encapsulation performance of the encapsulation layer 700.

Optionally, the light-emitting layer 400 includes an electron injection layer (EIL), an electron transport layer (ETL), a light-emitting material layer, a hole injection layer (HIL), and a hole transport layer (HTL).

The structural design in the present embodiment can be applied to other display panels 10 and can be selected according to the actual situation, which is not specifically limited in the present application.

An embodiments in a second aspect of the application further provides a display apparatus including a display panel 10 of any of embodiments in the first aspect described above. Since the display apparatus provided by the embodiment in the second aspect of the present application includes the display panel 10 of any of embodiments in the first aspect described above, therefore, the display apparatus provided by the embodiment in the second aspect of the present application has the beneficial effect of the display panel 10 of any of embodiments in the first aspect described above, which will not be repeated here.

The display apparatus in the embodiments of the present application include, but are not limited to, mobile phones, personal digital assistants (referred to as PDAs), tablet computers, e-books, televisions, access guards, intelligent fixed phones, consoles and other devices with display functions.

An embodiment in a third aspect of the present application further provides a method for manufacturing the display panel 10. The display panel 10 can be the display panel 10 provided by any of embodiments in the first aspect described above. Please refer to FIGS. 1 to 11 and further refer to FIG. 12. FIG. 12 is schematic flowchart of a method for manufacturing a display panel provided according to an embodiment of the present application. The manufacturing method includes the following steps.

In Step S01, manufacturing a substrate including a signal transmission layer and a signal shielding layer, wherein the signal shielding layer is located on a side of the signal transmission layer away from the substrate, and the signal shielding layer includes a first signal line and a light-transmitting shielding portion.

In step S02, manufacturing an isolation structure on the substrate, wherein the isolation structure encloses an isolation opening and a light-transmitting opening, the isolation opening is used for setting up a light-emitting unit, an orthographic projection of the light-transmitting opening on the substrate at least partially overlaps with an orthographic projection of the light-transmitting shielding portion on the substrate.

In step S03, manufacturing a touch layer on a side of the signal shielding layer away from the signal transmission layer.

According to the manufacturing method of the embodiment in the third aspect of the present application, the substrate 100 is manufactured by step S01, and the substrate 100 includes a signal-transmitting layer 110 and a signal shielding layer 120. Then the isolation structure 200 is manufactured by step S02. Finally, the touch layer 300 is manufactured by step S03. The isolation structure 200 is arranged on the substrate 100 and encloses a plurality of isolation openings 240 for isolating the light-emitting layer 400 to form light-emitting units 410 separated from each other, thereby reducing the crosstalk of carriers in the light-emitting layer 400 and improving the display effect of the display panel 10. In addition, the manufacturing of the light-emitting units 410 does not need to use a fine metal mask, which can reduce the development and use of the fine metal mask and reduce the manufacturing cost. The isolation structure 200 is provided with a light-transmitting opening 250, which can improve the transmittance of the display panel 10. The substrate 100 includes a signal transmission layer 110 and a signal shielding layer 120, the signal shielding layer 120 includes a first signal line 121 and a light-transmitting shielding portion 122, and the signal shielding layer 120 is located on a side of the signal transmission layer 110 away from the substrate 100. The orthographic projection of the light-transmitting opening 250 on the substrate 100 at least partially overlaps with an orthographic projection of the light-transmitting shielding portion 122 on the substrate 100, that is, the light-transmitting shielding portion 122 covers at least part of the light-transmitting opening 250, so that the touch signal of the touch layer 130 is at least partially shielded by the light-transmitting shielding portion 122 after passing through the light-transmitting opening, which makes improvements on the problem that the touch signal of the touch layer 300 and the array signal of the substrate 100 influence each other through the light-transmitting opening 250, thereby improving the usage performance of the OLED display product.

According to the above-mentioned embodiments of the present application, these embodiments do not describe all details exhaustively, nor do they limit the application to only the specific embodiments described. Obviously, according to the above description, many modifications and changes can be made. This specification selects and describes these embodiments in details, in order to better explain principles and practical applications of this application, such that those skilled in the art can make good use of this application and make modifications on the basis of this application. This application is only limited by the claims and their full scope and equivalents.

What is claimed is:

1. A display panel comprising:
a substrate comprising a signal transmission layer and signal shielding layer, the signal shielding layer located on a side of the signal transmission layer away from the substrate, and the signal shielding layer having at least one first signal line and a light-transmitting shielding portion;
a light-emitting unit disposed on the substrate;
an isolation structure located on a side of the substrate and defined with an isolation opening for receiving the light-emitting unit and a light-transmitting opening, and an orthographic projection of the light-transmitting opening on the substrate at least partially overlaps with an orthographic projection of the light-transmitting shielding portion on the substrate; and
a touch layer located on a side of the signal shielding layer away from the signal transmission layer.

2. The display panel of claim 1, wherein
the orthographic projection of the light-transmitting opening on the substrate is within the orthographic projection of the light-transmitting shielding portion on the substrate;
the light-transmitting shielding portion is connected with the at least one first signal line.

3. The display panel of claim 1, wherein the at least one first signal line comprises a plurality of first signal lines arranged side by side, adjacent first signal lines of the plurality of first signal lines are arranged at an interval and a gap is formed between the adjacent first signal lines, and the light-transmitting shielding portion is located in the gap.

4. The display panel of claim 3, wherein the light-transmitting shielding portion is electrically connected to one or more of the plurality of first signal lines adjacent to the light-transmitting shielding portion.

5. The display panel of claim 3, wherein one light-transmitting shielding portion is arranged corresponding to one light-transmitting opening.

6. The display panel of claim 3, wherein one light-transmitting shield portion is arranged corresponding to a plurality of light-transmitting openings.

7. The display panel of claim 1, wherein the orthographic projection of the light-transmitting shielding portion on the substrate at least partially overlaps with an orthographic projection of the first signal line on the substrate.

8. The display panel of claim 7, wherein the orthographic projection of the first signal line on the substrate is within the orthographic projection of the light-transmitting shielding portion on the substrate.

9. The display panel of claim 1, wherein the light-transmitting shielding portion encloses a first opening, the signal shielding layer further comprises a second signal line, the first signal line and the second signal line are located in the first opening, and the second signal line is spaced and insulated from the light-transmitting shielding portion and the first signal line.

10. The display panel of claim 9, wherein
both ends of the first signal line are lapped to the light-transmitting shielding portion; and
the second signal line comprises a data signal line.

11. The display panel of claim 1, wherein
a material of the light-transmitting shielding portion is different from that of the first signal line, and the first signal line is a non-light-transmission conductive material.

12. The display panel of claim 11, wherein
the light-transmitting shielding portion comprises indium tin oxide or indium zinc oxide; and
each of the at least one first signal line comprises at least one of a power signal line and a reference signal line.

13. The display panel of claim 1, wherein the display panel further comprises:
a light-emitting layer located on a side of the substrate, the light-emitting layer including the light-emitting unit located in the isolation opening;
a first electrode layer located on a side of the light-emitting layer away from the substrate, the first electrode layer including a first electrode located in the isolation opening, and the first electrode being electrically connected with the isolation structure.

14. The display panel of claim 13, wherein
an orthographic projection of the light-emitting unit on the substrate is within an orthographic projection of a corresponding first electrode on the substrate; and
the light-emitting unit is spaced from the isolation structure.

15. The display panel of claim 14, wherein
the isolation structure comprises a first conductive layer and a second layer located on a side of the first conductive layer away from the substrate, and an orthographic projection of the first conductive layer on the substrate is within an orthographic projection of the second layer on the substrate.

16. The display panel of claim 15, wherein
the second layer comprises a conductive material or an insulation material; and
the second layer comprises a metal material, and a material of the first conductive layer is different from that of the second layer.

17. The display panel of claim 15, wherein
the isolation structure further comprises a third layer located on a side of the first conductive layer facing the substrate, and the orthographic projection of the first conductive layer on the substrate is within an orthographic projection of the third layer on the substrate.

18. The display panel of claim 1, wherein the display panel further comprises:
a pixel definition layer located on a side of the substrate, the pixel definition layer including a pixel limiting portion and a pixel opening enclosed by the pixel limiting portion, the pixel opening being communicated with the isolation opening, and the light-emitting unit being located in the pixel opening.

19. The display panel of claim 13, wherein
the isolation structure is located on a side of the pixel limiting portion away from the substrate;
the pixel limiting portion is provided with a second opening, and the isolation structure is located in the second opening; and
the display panel further comprises a pixel electrode exposed by the pixel opening.

20. A display apparatus comprising the display panel of claim 1.
